(19) United States
(12) Patent Application Publication
(10) Pub. No.: US 2025/0231864 A1
(43) Pub. Date: Jul. 17, 2025

(54) STORAGE DEVICE PERFORMING POWER-ON SEQUENCE, ELECTRONIC DEVICE INCLUDING THE SAME, AND METHOD OF OPERATING THE SAME

(71) Applicant: Samsung Electronics Co., Ltd., Suwon-si (KR)

(72) Inventors: Taewook HEO, Suwon-si (KR); Ho-Jin CHUN, Suwon-si (KR); Hyoungtaek LIM, Suwon-si (KR)

(73) Assignee: Samsung Electronics Co., Ltd., Suwon-si (KR)

(21) Appl. No.: 18/883,132

(22) Filed: Sep. 12, 2024

(30) Foreign Application Priority Data
Jan. 12, 2024 (KR) 10-2024-0005271

(51) Int. Cl. G06F 12/02; G11C 5/14

(52) U.S. Cl. CPC G06F 12/0223; G11C 5/14

(57) ABSTRACT

Disclosed are methods of operating a storage device which communicates with a host device includes receiving a first power supply voltage and a second power supply voltage from the host device, executing, by a micro controller unit (MCU) of the storage device, a first power-on sequence for sequentially generating a plurality of internal voltages of the storage device based on the second power supply voltage, detecting, by the MCU, a first power failure corresponding to the first power-on sequence, and performing, by the MCU, a second power-on sequence for sequentially generating the plurality of internal voltages in response to detecting the first power failure.

### CROSS-REFERENCE TO RELATED APPLICATIONS

This application claims priority under 35 U.S.C. § 119 to Korean Patent Application No. 10-2024-0005271 filed on Jan. 12, 2024, in the Korean Intellectual Property Office, the disclosures of which are incorporated by reference herein in their entireties.

### BACKGROUND

Embodiments of the present disclosure described herein relate to storage devices, and more particularly, relate to storage devices performing a power-on sequence, electronic devices including the same, and methods of operating the same.

A memory device stores data in response to a write request and outputs data stored therein in response to a read request. For example, the memory device is classified as a volatile memory device, which loses data stored therein when a power is turned off, such as a dynamic random access memory (DRAM) device or a static RAM (SRAM) device, or a non-volatile memory device, which retains data stored therein even when a power is turned off, such as a flash memory device, a phase-change RAM (PRAM), a magnetic RAM (MRAM), or a resistive RAM (RRAM).

The non-volatile memory device may be also referred to as a “storage device” storing a large amount of data. The storage device may include various function blocks for directly or indirectly data management operations such as a read operation, a write operation, and an erase operation. The storage device may sequentially generate internal voltages to be provided to the function blocks, based on a power supply voltage received from the outside. An abnormal situation associated with some of the internal voltages may occur due to transient or permanent factors. There may be required a technique for solving the abnormal situation.

### SUMMARY

Embodiments of the present disclosure provide storage devices performing a power-on sequence, electronic devices including the same, and methods of operating the same.

According to some example embodiments, a method of operating a storage device which communicates with a host device includes receiving a first power supply voltage and a second power supply voltage from the host device, executing, by a micro controller unit (MCU) of the storage device, a first power-on sequence for sequentially generating a plurality of internal voltages of the storage device based on the second power supply voltage, detecting, by the MCU, a first power failure corresponding to the first power-on sequence, and performing, by the MCU, a second power-on sequence for sequentially generating the plurality of internal voltages in response to detecting the first power failure.

According to some example embodiments, a storage device includes a storage controller, a non-volatile memory device, a power supply circuit that includes a plurality of power blocks generating a plurality of internal voltages to be provided to the storage controller and the non-volatile memory device based on a first power supply voltage received from a host device, and a micro controller unit (MCU) that receives a second power supply voltage lower than the first power supply voltage from the host device and executes a first power-on sequence based on the second power supply voltage, and the power supply circuit is configured to sequentially active the plurality of power blocks depending on an enablement order defined in the first power-on sequence under control of the MCU.

According to some example embodiments, an electronic device includes a host device that generates a main voltage and an auxiliary voltage, and a storage device that includes a power supply circuit receiving the main voltage and a micro controller unit (MCU) receiving the auxiliary voltage. The MCU executes a power-on sequence based on the auxiliary voltage, detects a power failure corresponding to the power-on sequence, and again performs the power-on sequence in response to detecting the power failure, and the storage device is configured to sequentially active a plurality of power blocks of the power supply circuit depending on an enablement order defined in the power-on sequence.

### BRIEF DESCRIPTION OF THE FIGURES

The above and other objects and features of the present disclosure will become apparent by describing in detail example embodiments thereof with reference to the accompanying drawings.

FIG. 1 is a block diagram of an electronic device according to some example embodiments of the present disclosure.

FIG. 2 is a flowchart describing a method of operating a conventional storage device.

FIG. 3 is a flowchart describing a method of operating a storage device according to some example embodiments of the present disclosure.

FIG. 4 is a block diagram describing a storage device according to some example embodiments of the present disclosure.

FIG. 5 is a block diagram illustrating an example of a storage device of FIG. 4, according to some example embodiments of the present disclosure.

FIG. 6 is a diagram describing a method of operating a storage device according to some example embodiments of the present disclosure.

FIG. 7 is a diagram describing a method of operating a storage device according to some example embodiments of the present disclosure.

FIG. 8 is a diagram describing a method of operating a storage device according to some example embodiments of the present disclosure.

FIG. 9 is a flowchart describing a method of operating a storage device according to some example embodiments of the present disclosure.

FIG. 10 is a flowchart describing an example of some operations of FIG. 9, according to some example embodiments of the present disclosure.

FIG. 11 is a flowchart describing an example of some operations of FIG. 9, according to some example embodiments of the present disclosure.

FIG. 12 is a flowchart describing an example of some operations of FIG. 9, according to some example embodiments of the present disclosure.

FIG. 13 is a flowchart describing an example of some operations of FIG. 9, according to some example embodiments of the present disclosure.

FIG. 14 is a flowchart describing a method of operating a storage device according to some example embodiments of the present disclosure.

### DETAILED DESCRIPTION

Below, example embodiments of the present disclosure will be described in detail and clearly to such an extent that one skilled in the art may carry out example embodiments of the present disclosure easily.

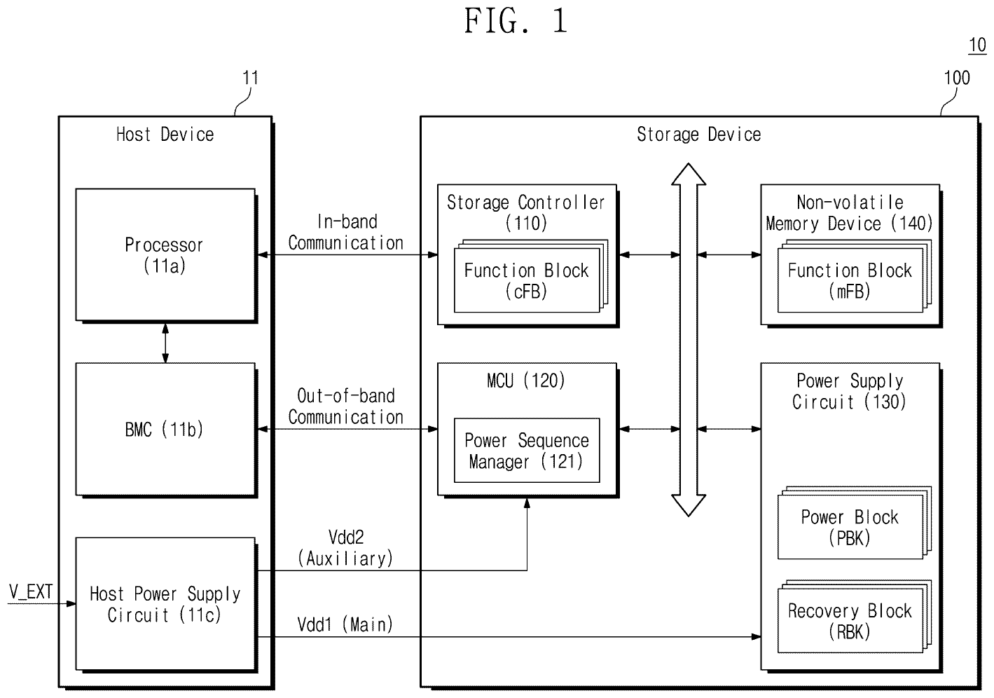

FIG. 1 is a block diagram of an electronic device according to some example embodiments of the present disclosure. Referring to FIG. 1, an electronic device 10 may include a computing system configured to process a variety of information or to store the processed information as data. In some example embodiments, the electronic device 10 may be implemented with a personal computer (PC), a notebook, a laptop, a server, a workstation, a tablet PC, a smartphone, a digital camera, a black box, etc. The electronic device 10 may include a host device 11 and a storage device 100.

The host device 11 may control an overall operation of the electronic device 10. For example, the host device 11 may store data in the storage device 100, may manage hardware information of the storage device 100 to maintain the reliability of the stored data, and may provide voltages necessary (or alternatively, desired, selected, or beneficial) to drive the storage device 100.

The host device 11 may be driven based on an external voltage V_EXT. For example, the external voltage V_EXT which is a high voltage may be an AC voltage, but the present disclosure is not limited thereto. The host device 11 may include a processor 11a, a baseboard management controller (BMC) 11b, and a host power supply circuit 11c.

The processor 11a may store data in the storage device 100, may read data stored in the storage device 100, or may delete data stored in the storage device 100. For example, the data may include a variety of information to be provided to the user, such as an image, a video, a text, and/or a voice.

The processor 11a may be implemented as one or more of various processing units such as a central processing unit (CPU), a graphic processing unit (GPU), and a neural processing unit (NPU). The processor 11a may perform in-band communication with a storage controller 110 of the storage device 100.

The BMC 11b may manage hardware information of the storage device 100. For example, the hardware information may include sensed values of physical environments such as a temperature, a voltage, a current, and humidity, may include reliability information such as the number of program/erase (P/E) cycles, program count information, erase count information, read count information, error bit count information, and threshold voltage distribution information, and/or may include a result of analyzing the sensed values or the reliability information (e.g., an error message according to a hardware failure).

The BMC 11b may receive the hardware information from a micro controller unit (MCU) 120 of the storage device 100 or may provide the hardware information to the MCU 120. The BMC 11b may perform out-of-band communication with the MCU 120 of the storage device 100.

The out-of-band communication may be performed without intervention (e.g., independently of) of the processor 11a and the storage controller 110. A communication interface for the out-of-band communication may be provided independently of a communication interface for the in-band communication. For example, the out-of-band communication may physically use a system management bus (SMBus).

In some example embodiments, the communication interface for the out-of-band communication may support various communication protocols. For example, the communication interface for the out-of-band communication may support at least one of various kinds of protocols such as an open computer project (OCP) standard, a platform level data model (PLDM) standard, a network controller sideband interface (NC-SI) standard, a Redfish standard, a non-volatile memory express management interface (NVMe_MI) standard, and a management component transport protocol (MCTP) standard.

The host power supply circuit 11c may receive the external voltage V_EXT. The host power supply circuit 11c may generate a first power supply voltage Vdd1 and a second power supply voltage Vdd2 based on the external voltage V_EXT. The first power supply voltage Vdd1 may be referred to as a “main voltage”. The second power supply voltage Vdd2 may referred to as an “auxiliary voltage”. The host power supply circuit 11c may provide the first power supply voltage Vdd1 to a power supply circuit 130 of the storage device 100. The host power supply circuit 11c may provide the second power supply voltage Vdd2 to the MCU 120 of the storage device 100.

A voltage level of the first power supply voltage Vdd1 may be higher than a voltage level of the second power supply voltage Vdd2. For example, the first power supply voltage Vdd1 may be a DC voltage whose voltage level is about 12 V. The second power supply voltage Vdd2 may be a DC voltage whose voltage level is about 3.3 V. However, the present disclosure is not limited thereto. For example, the voltage levels of the first and second power supply voltages Vdd1 and Vdd2 may be variously changed or modified depending on the communication protocol or the specifications of the storage device 100.

The storage device 100 may include the storage controller 110, the MCU 120, the power supply circuit 130, and a non-volatile memory device 140. The storage device 100 may operate based on the first and second power supply voltages Vdd1 and Vdd2 received from the host device 11. Under control of the host device 11, the storage device 100 may store data or may provide the stored data to the host device 11.

The storage controller 110 may perform the in-band communication with the processor 11a of the host device 11. The storage controller 110 may store data received by the in-band communication in the non-volatile memory device 140 or may provide data stored in the non-volatile memory device 140 to the processor 11a through the in-band communication.

The storage controller 110 may include a plurality of function blocks cFB. For example, the plurality of function blocks cFB may be implemented with devices, which perform various functions, such as an internal processor, an internal volatile memory device, an error correction code (ECC) engine, a host interface circuit, and a non-volatile memory interface circuit. The plurality of function blocks cFB may be driven based on internal voltages provided from the power supply circuit 130.

The MCU 120 may manage hardware information. The MCU 120 may be driven based on the second power supply voltage Vdd2. The second power supply voltage Vdd2 may be a constant power supply voltage (or an always-supplied voltage). As the MCU 120 is driven based on the second power supply voltage Vdd2 being a constant power supply voltage, in addition to the internal voltage provided from the power supply circuit 130, the stability of power management of the storage device 100 may be improved.

The MCU 120 may perform and the out-of-band communication with the BMC 11b of the host device 11. The MCU 120 may provide hardware information to the BMC 11b through the out-of-band communication or may provide an error message generated by the analysis of the hardware information to the BMC 11b through the out-of-band communication.

The MCU 120 may include a power sequence manager 121. The power sequence manager 121 may control the power supply circuit 130 to perform a power-on sequence, may update the power-on sequence, and may execute a power-off sequence. The power-on sequence may indicate an operation of sequentially generating internal voltages necessary (or alternatively, desired, selected, or beneficial) for the storage device 100. The power-off sequence may indicate an operation of normally deactivating the internal voltages generated by the power-on sequence. That is, the power sequence manager 121 may manage the power-on sequence and the power-off sequence.

The power sequence manager 121 may monitor whether the power-on sequence is normally executed. The power sequence manager 121 may monitor whether the internal voltages generated by the power-on sequence are normally maintained. The power sequence manager 121 may detect a power failure based on the monitoring operation. The power sequence manager 121 may perform a subsequent operation (e.g., an operation of activating a recovery block RBK or an operation of outputting an error message to the host device 11), based on the detected power failure.

The power sequence manager 121 may be implemented by hardware, software, or a combination thereof. When at least a part of the power sequence manager 121 is implemented by software, the MCU 120 may include an embedded processor or an embedded memory. The embedded processor may implement functions (e.g., the power-on sequence and the power-off sequence) of the power sequence manager 121 by loading instructions to the embedded memory and executing the loaded instructions. The embedded processor may be implemented with a processing circuit which is capable of executing a machine code or an assembly language. The embedded memory may be implemented with an electrically erasable programmable read-only memory (EEPROM).

The power supply circuit 130 may receive the first power supply voltage Vdd1 from the host power supply circuit 11c of the host device 11. The power supply circuit 130 may generate a plurality of internal voltages based on the first power supply voltage Vdd1. The power supply circuit 130 may provide the plurality of internal voltages to the MCU 120, the plurality of function blocks cFB of the storage controller 110, and a plurality of function blocks mFB of the non-volatile memory device 140.

The power supply circuit 130 may include a plurality of power blocks PBK. Each of the plurality of power blocks PBK may generate internal voltages necessary (or alternatively, desired, selected, or beneficial) for sub-components (e.g., the MCU 120, the function blocks cFB, and the function blocks mFB) of the storage device 100. The internal voltages may be utilized as driving voltages for the sub-components of the storage device 100. For example, each of the power blocks PBK may be implemented by using a power management integrated circuit (PMIC), a voltage regulator, etc.

The power supply circuit 130 may further include the plurality of recovery blocks RBK. The plurality of recovery blocks RBK may replace power blocks PBK permanently damaged (for example, damaged such that functionality ceases and/or cannot be repaired while device is intact, destroyed, etc.) from among the plurality of power blocks PBK. In the power-on sequence, the replaced recovery block RBK may perform a function of the damaged power block PBK (for example, may generate an internal voltage corresponding to the damaged power block PBK). As the damaged power block PBK is replaced with the recovery block RBK, the stable power supply may be guaranteed. As in the power block PBK, each of the recovery blocks RBK may be implemented by using a PMIC, a voltage regulator, etc.

The power supply circuit 130 may sequentially generate internal voltages under control of the power sequence manager 121 of the MCU 120. For example, depending on an enablement order defined in the power-on sequence, the power sequence manager 121 may sequentially activate valid power blocks PBK among the plurality of power blocks PBK and recovery blocks RBK, which are used to replace failed power blocks PBK, from among the plurality of recovery blocks RBK. The activated blocks may generate internal voltages based on the first power supply voltage Vdd1.

The non-volatile memory device 140 may store data under control of the storage controller 110. The non-volatile memory device 140 may retain data stored therein even though the power supplied to the non-volatile memory device 140 is turned off. For example, the non-volatile memory device 140 may be implemented with a flash memory device, a phase-change RAM (PRAM), a magnetic RAM (MRAM), a resistive RAM (RRAM), etc.

The non-volatile memory device 140 may include the plurality of function blocks mFB. For example, the plurality of function blocks mFB may be implemented with devices, which perform various functions, such as a control logic circuit, a read/write voltage generator, a row decoder, a columns decoder, a memory block, a page buffer circuit, a sense amplifier, and a write driver. The plurality of function blocks mFB may be driven based on internal voltages provided from the power supply circuit 130.

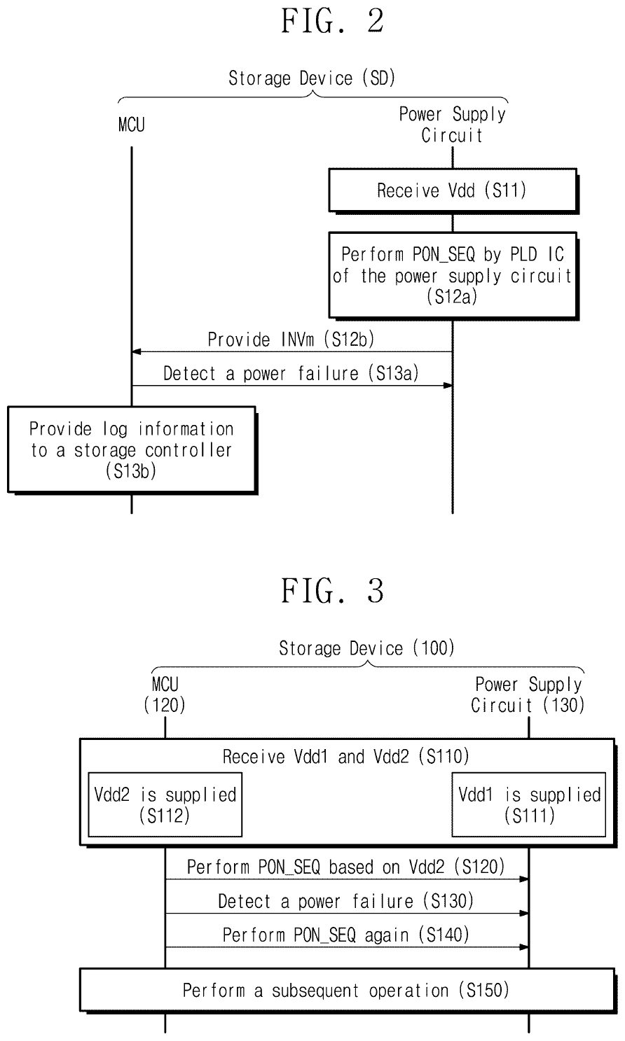

FIG. 2 is a flowchart describing a method of operating a conventional storage device. Referring to FIG. 2, a conventional storage device SD may communicate with a host device. The conventional storage device SD may include an MCU and a power supply circuit. The conventional storage device SD is only provided for better understanding of the present disclosure and is not intended to limit the scope of the present disclosure. The conventional storage device SD may include characteristics which are not disclosed in the documents of the information disclosure statement.

In operation S11, the power supply circuit may receive a power supply voltage Vdd from the host device. The power supply voltage Vdd may be also referred to as a “main voltage”.

In operation S12a, a programmable logic device integrated circuit (PLD IC) of the power supply circuit may execute a power-on sequence PON_SEQ. The PLD IC may be driven based on the power supply voltage Vdd. The power-on sequence PON_SEQ may indicate sequentially generating a plurality of internal voltages necessary (or alternatively, desired, selected, or beneficial) for the conventional storage device SD depending on an enablement order.

The PLD IC may be a circuit which is difficult to reprogram. For example, after sequence instructions corresponding to the power-on sequence PON_SEQ are programmed in the PLD IC, it may be difficult to change or erase the programmed instructions. Due to the physical limitation of the PLD IC, it may be difficult to actively change the power-on sequence PON_SEQ.

In operation S12b, the power supply circuit may provide the MCU with an MCU internal voltage INVm among the plurality of internal voltages generated depending on the power-on sequence PON_SEQ. The MCU internal voltage INVm may refer to an internal voltage dedicated for the MCU from among the plurality of internal voltages. The MCU may be activated based on the MCU internal voltage INVm. In this case, the MCU may be driven only based on the MCU internal voltage INVm without receiving a separate constant voltage (for example, an auxiliary voltage) from the host device. The MCU may be vulnerable to the voltage abnormality of the MCU internal voltage INVm.

In operation S13a, the MCU may monitor whether the voltage abnormality of the internal voltages of the power supply circuit occurs. Because the MCU is driven based on the MCU internal voltage INVm, when the voltage abnormality of the MCU internal voltage INVm occurs, the MCU may fail to normally monitor the power supply circuit. In some cases, the MCU may detect a power failure of the power supply circuit through the monitoring operation.

In operation S13b, the MCU may generate log information describing the detected power failure. The MCU may provide the log information to a storage controller. The storage controller may provide an error message to the host device based on the log information. Because the MCU of the conventional storage device SD does not execute the power-on sequence PON_SEQ, even though the power failure is detected, active measures (e.g., the re-execution of the power-on sequence PON_SEQ and the activation of a recovery block to overcome the power failure) may be impossible.

Also, because the storage controller is driven based on the internal voltage generated by the power supply circuit, when the voltage abnormality of the internal voltage to be provided to the storage controller occurs, the storage controller may be difficult to normally process the log information. That is, when the abnormality of the internal voltage or the power supply circuit occurs, the conventional storage device SD may be difficult to notify a main cause of the power failure to the host device.

FIG. 3 is a flowchart describing a method of operating a storage device according to some example embodiments of the present disclosure. Referring to FIG. 3, the storage device 100 may communicate with the host device 11 of FIG. 1. The storage device 100 may include the MCU 120 and the power supply circuit 130.

In operation S110, the storage device 100 may receive the first power supply voltage Vdd1 and the second power supply voltage Vdd2 from the host device 11 of FIG. 1. The first power supply voltage Vdd1 may be referred to as a “main voltage”, and the second power supply voltage Vdd2 may be referred to as an “auxiliary voltage”.

Operation S110 may include operation S111 and operation S112. In operation S111, the power supply circuit 130 may receive the first power supply voltage Vdd1. In operation S112, the MCU 120 may receive the second power supply voltage Vdd2. The second power supply voltage Vdd2 may be a constant power supply voltage which is provided independently of the first power supply voltage Vdd1. Because the MCU 120 is driven based on the second power supply voltage Vdd2 being a constant power supply voltage, a stable hardware management operation may be guaranteed.

In operation S120, the MCU 120 may execute the power-on sequence PON_SEQ based on the second power supply voltage Vdd2. For example, depending on an enablement order defined in the power-on sequence PON_SEQ, the MCU 120 may sequentially activate power blocks in the power supply circuit 130. The sequentially activated power blocks may provide internal voltages to function blocks in the storage device 100 and may provide an MCU internal voltage to the MCU 120. The MCU 120 may be driven based on both the second power supply voltage Vdd2 and the MCU internal voltage.

In operation S130, the MCU 120 may monitor whether the power-on sequence PON_SEQ is normally executed. The MCU 120 may monitor whether the voltage abnormality of a plurality of internal voltages generated by the power-on sequence PON_SEQ occurs. The MCU 120 may detect a power failure based on the monitoring operation. The MCU 120 may generate log information describing the detected power failure. The log information may be managed by the MCU 120 or may be provided to a storage controller.

In operation S140, the MCU 120 may again execute the power-on sequence PON_SEQ based on detecting the power failure. An enablement order defined in the power-on sequence PON_SEQ again performed may be the same as the enablement order defined in the power-on sequence PON_SEQ in operation S120. When the power failure is based on a transient cause, the power failure may be overcome by executing the same power-on sequence PON_SEQ.

Because the MCU 120 executes the power-on sequence PON_SEQ, unlike the MCU of the conventional storage device SD of FIG. 2, the MCU 120 may perform the active measure such as the execution of the power-on sequence PON_SEQ, in addition to a passive measure such as the generation of log information about the power failure.

In operation S150, the MCU 120 may perform a subsequent operation depending on a result of the power-on sequence PON_SEQ again executed. For example, when the power failure is based on a transient cause, the power failure may be overcome by again executing the power-on sequence PON_SEQ. After the MCU 120 successfully executes the power-on sequence PON_SEQ, the MCU 120 may periodically monitor the voltage abnormality of the internal voltages generated by the power-on sequence PON_SEQ.

As another example, when the power failure is based on a permanent cause, the power-on sequence PON_SEQ again executed may fail. After the MCU 120 fails in the execution of the power-on sequence PON_SEQ, the MCU 120 may determine whether a recovery block for replacing a power block causing the power failure exists.

When the recovery block exists, the MCU 120 may activate the recovery block instead of the failed power block, may change the power-on sequence PON_SEQ such that the recovery block is applied, and may perform the changed power-on sequence PON_SEQ. Unlike the PLD IC of the conventional storage device SD of FIG. 2, because a memory (e.g., the EEPROM of the MCU 120) which stores a sequence instruction of the power-on sequence PON_SEQ is capable of being reprogrammed, the MCU 120 may change the sequence instruction corresponding to the power-on sequence PON_SEQ. That is, the MCU 120 may flexibly execute the power-on sequence PON_SEQ by applying the power failure to the power-on sequence PON_SEQ.

In contrast, when the recovery block does not exist, the MCU 120 may provide an error message, which describes that the power failure is permanent and is incapable of being solved, to the host device 11 of FIG. 1 through the out-of-band communication. Because the error message is transmitted to the host device 11 of FIG. 1 by using not the in-band communication but the out-of-band communication, even though the voltage abnormality is caused in association with the internal voltage provided to the storage controller 110 of FIG. 1, the MCU 120 may stably transmit the error message to the host device 11 of FIG. 1.

For example, according to some example embodiments, there may be an increase in speed, accuracy, device longevity, and/or power efficiency of the storage device based on the above methods. Therefore, the improved devices and methods overcome the deficiencies of the conventional devices and methods of powering on storage devices while reducing resource consumption, device longevity, data accuracy, and increasing data clarity. Further, there is an improvement in experience provided to the user, and efficiency of resource distribution in the whole system may be improved.

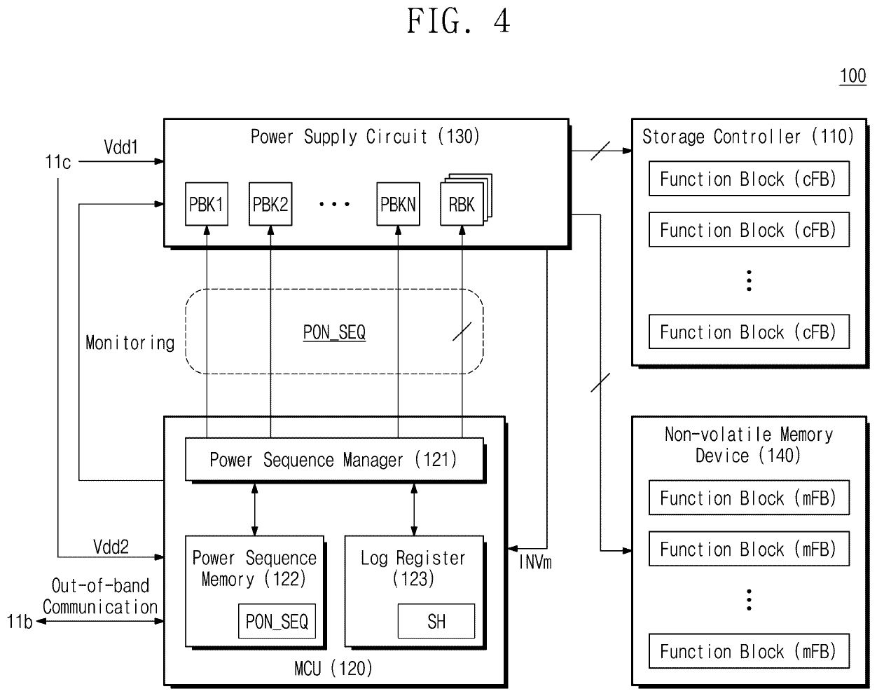

FIG. 4 is a block diagram describing a storage device according to some example embodiments of the present disclosure. Referring to FIG. 4, the storage device 100 may correspond to the storage device 100 of FIG. 1. The storage device 100 may communicate with the BMC 11b and the host power supply circuit 11c of the host device 11 of FIG. 1.

The storage device 100 may include the storage controller 110, the MCU 120, the power supply circuit 130, and the non-volatile memory device 140. The power supply circuit 130 may receive the first power supply voltage Vdd1 from the host power supply circuit 11c. The MCU 120 may receive the second power supply voltage Vdd2 from the host power supply circuit 11c. The storage controller 110 may include the plurality of function blocks cFB. The non-volatile memory device 140 may include the plurality of function blocks mFB.

The MCU 120 may include the power sequence manager 121, a power sequence memory 122, and a log register 123. The power sequence manager 121 may execute the power-on sequence PON_SEQ. The power sequence memory 122 may store a sequence instruction corresponding to the power-on sequence PON_SEQ. The log register 123 may store sequence history information SH. The power sequence memory 122 and the log register 123 may be implemented by using the EEPROM present in the MCU 120 or may be implemented by using separate memory devices present in the MCU 120.

The sequence history information SH may include execution history information of the power-on sequence PON_SEQ, fail history information of the power-on sequence PON_SEQ, change history information of the power-on sequence PON_SEQ, execution history information of a power-off sequence POFF_SEQ, power failure history information, power failure recovery history information, etc.

The power sequence manager 121 may be activated based on the second power supply voltage Vdd2. The activated power sequence manager 121 may load the sequence instruction from the power sequence memory 122 and may execute the power-on sequence PON_SEQ based on the loaded sequence instruction. The power-on sequence PON_SEQ may indicate sequentially activating at least some of a plurality of power blocks PBK1 to PBKN and the plurality of recovery blocks RBK depending on an enablement order. The power sequence manager 121 may update the sequence history information SH of the log register 123, based on executing the power-on sequence PON_SEQ.

The power supply circuit 130 may be activated depending on the power-on sequence PON_SEQ. For example, valid power blocks among the plurality of power blocks PBK1 to PBKN and recovery blocks replacing failed power blocks from among the plurality of recovery blocks RBK may be sequentially activated depending on an enablement order defined in the power-on sequence PON_SEQ. The sequentially activated blocks may provide internal voltages to the function blocks cFB of the storage controller 110 and the function blocks mFB of the non-volatile memory device 140. Also, one of the sequentially activated blocks may provide the MCU internal voltage INVm to the MCU 120.

The power sequence manager 121 of the MCU 120 may monitor the power supply circuit 130. For example, the power sequence manager 121 may monitor whether the power-on sequence PON_SEQ is normally executed. After the power-on sequence PON_SEQ is normally executed, the power sequence manager 121 may monitor the voltage abnormality of the internal voltages and the MCU internal voltage INVm. The power sequence manager 121 may detect a power failure based on the monitoring operation. Because the power sequence manager 121 is driven based on both the second power supply voltage Vdd2 and the MCU internal voltage INVm, the power sequence manager 121 may stably operate.

When the power failure is detected, the power sequence manager 121 may again execute the power-on sequence PON_SEQ. The power sequence manager 121 may update the sequence history information SH of the log register 123, based on again executing the power-on sequence PON_SEQ.

When the power-on sequence PON_SEQ again executed succeeds, the power sequence manager 121 may monitor whether the voltage abnormality is caused in associated with the internal voltages. When the power-on sequence PON_SEQ again executed fails, the power sequence manager 121 may determine whether the recovery block RBK capable of replacing a failed power block causing the power failure exists.

When the recovery block RBK exists, the power sequence manager 121 may replace the failed power block with the recovery block RBK, may execute the power-on sequence PON_SEQ including the replaced recovery block RBK, may update the sequence instruction of the power sequence memory 122, and may update the sequence history information SH of the log register 123.

When the recovery block RBK does not exist, the power sequence manager 121 may provide an error message, which describes that the power failure is permanent and is incapable of being solved, to the BMC 11b through the out-of-band communication.

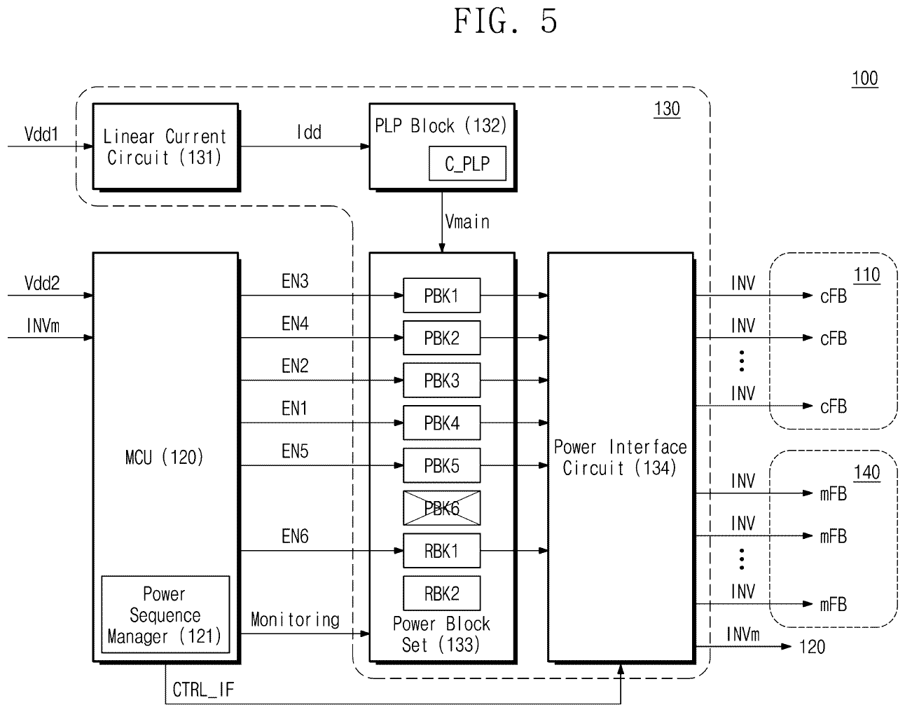

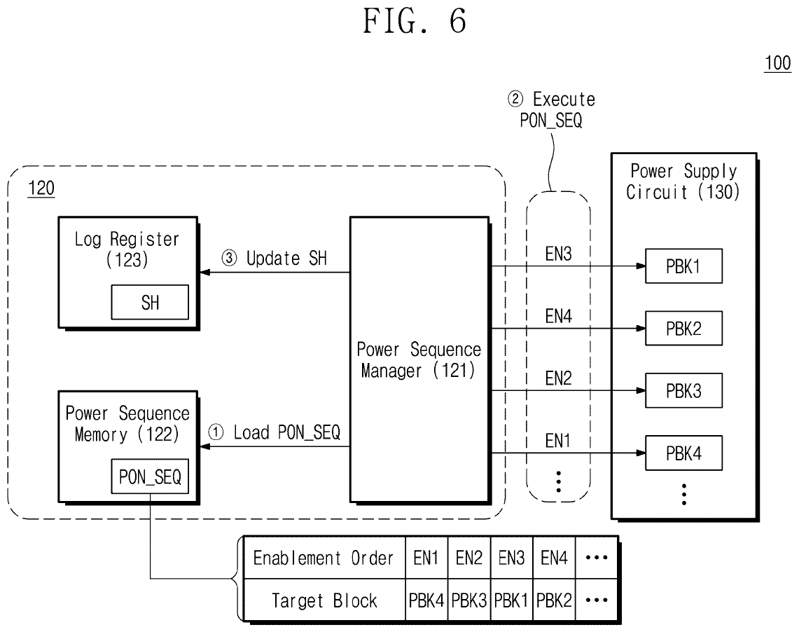

FIG. 5 is a block diagram illustrating an example of a storage device of FIG. 4, according to some example embodiments of the present disclosure. Referring to FIGS. 4 and 5, the storage device 100 may include the storage controller 110, the MCU 120, the power supply circuit 130, and the non-volatile memory device 140. The power supply circuit 130 may receive the first power supply voltage Vdd1 from the host power supply circuit 11c. The MCU 120 may receive the second power supply voltage Vdd2 from the host power supply circuit 11c.

The MCU 120 may include the power sequence manager 121. The power sequence manager 121 may execute the power-on sequence PON_SEQ. For example, the power-on sequence PON_SEQ may include sequentially providing first to sixth enable signals EN1 to EN6 to the power supply circuit 130.

The power sequence manager 121 may monitor whether the power-on sequence PON_SEQ is normally executed. The power sequence manager 121 may monitor whether a voltage causing the voltage abnormality is present in internal voltages INV and the MCU internal voltage INVm generated by the power-on sequence PON_SEQ. The power sequence manager 121 may determine whether the power failure occurs, through the monitoring operation.

When it is determined that the power failure occurs, the power sequence manager 121 may again execute the power-on sequence PON_SEQ. The power sequence manager 121 may replace a power block, which causes the power failure in the power-on sequence PON_SEQ again executed, with a recovery block.

For example, when the power failure is repeated in the sixth power block PBK6 corresponding to the sixth enable signal EN6, the power sequence manager 121 may replace the sixth power block PBK6 with a first recovery block RBK1 such that the first recovery block RBK1 among first and second recovery blocks RBK1 and RBK2 instead manages a power corresponding to the sixth enable signal EN6.

Afterwards, the power sequence manager 121 may control a power interface circuit 134 through a control interface signal CTRL_IF such that a function block (e.g., the function block cFB, the function block mFB, or the MCU 120) corresponding to the sixth power block PBK6 is electrically connected to the first recovery block RBK1. The corresponding function block may be provided with the internal voltage INV or INVm from the first recovery block RBK1 instead of the sixth power block PBK6.

Under control of the MCU 120, the power supply circuit 130 may provide the corresponding internal voltages INV to the function blocks cFB of the storage controller 110, may provide the corresponding internal voltages INV to the function blocks mFB of the non-volatile memory device 140, and may provide the MCU internal voltage INVm to the MCU 120. The power supply circuit 130 may include a linear current circuit 131, a power loss protection (PLP) block 132, a power block set 133, and the power interface circuit 134.

The linear current circuit 131 may receive the first power supply voltage Vdd1. The linear current circuit 131 may generate a power current Idd whose intensity is uniform, based on the first power supply voltage Vdd1. The linear current circuit 131 may provide the power current Idd to the PLP block 132.

The PLP block 132 may include a PLP capacitor C_PLP. The PLP capacitor C_PLP may be charged to a main power supply voltage Vmain based on the power current Idd. Even though the first power supply voltage Vdd1 or the power current Idd is blocked, the PLP capacitor C_PLP may provide the power block set 133 with the main power supply voltage Vmain as much as a time corresponding to the capacitance of the PLP capacitor C_PLP. The power block set 133 may include the first to sixth power blocks PBK1 to PBK6 and the first and second recovery blocks RBK1 and RBK2. For better understanding of the present disclosure, the description is given as the number of power blocks is 6 and the number of recovery blocks is 2. However, the number of power blocks may be more than or less than 6, and the number of recovery blocks may be more than or less than 2.

Some of the blocks PBK1 to PBK6, RBK1, and RBK2 of the power block set 133 may be sequentially activated in response to the first to sixth enable signals EN1 to EN6. For example, before a permanent power failure of the sixth power block PBK6 is detected, the blocks PBK4, PBK3, PBK1, PBK2, PBK5, and PBK6 may be sequentially activated in response to the first to sixth enable signals EN1 to EN6. As another example, after the failed sixth power block PBK6 is replaced with the first recovery block RBK1, the blocks PBK4, PBK3, PBK1, PBK2, PBK5, and RBK1 may be sequentially activated in response to the first to sixth enable signals EN1 to EN6.

A block activated in response to the corresponding enable signal may generate an internal voltage based on the main power supply voltage Vmain and may output the internal voltage to the power interface circuit 134.

The power interface circuit 134 may provide internal voltages received from the power block set 133 to relevant components. For example, the power interface circuit 134 may receive the plurality of internal voltages INV and the MCU internal voltage INVm from the power block set 133. The power interface circuit 134 may provide some of the plurality of internal voltages INV to the function blocks cFB of the storage controller 110, may provide the others of the plurality of internal voltages INV to the non-volatile memory device 140, and may provide the MCU internal voltage INVm to the MCU 120.

Assuming that a power block or a previously replaced recovery block is faulty, in the case where the failed block is replaced with a new recovery block, the power interface circuit 134 may identify the new recovery block based on the control interface signal CTRL_IF received from the MCU 120 and may provide an internal voltage received from the identified recovery block to a function block corresponding to the failed block.

FIG. 6 is a diagram describing a method of operating a storage device according to some example embodiments of the present disclosure. Referring to FIG. 6, the storage device 100 may include the MCU 120 and the power supply circuit 130. The MCU 120 may include the power sequence manager 121, the power sequence memory 122, and the log register 123. The power supply circuit 130 may include a plurality of power blocks such as the first to fourth power blocks PBK1 to PBK4.

Below, a method of operating the storage device 100 according to some example embodiments of the present disclosure will be described in detail.

In a first operation \textcircled{1}, the power sequence manager 121 may load a sequence instruction corresponding to the power-on sequence PON_SEQ from the power sequence memory 122. The sequence instruction may define an enablement order of power blocks. For example, the sequence instruction may include an enablement order item and a target block item. The enablement order item may sequentially list a plurality of enable signals such as the first to fourth enable signals EN1 to EN4. The target block item may sequentially list a plurality of blocks respectively mapped to the plurality of enable signals. The first to fourth enable signals EN1 to EN4 may be respectively mapped to the blocks PBK4, PBK3, PBK1, and PBK2.

In a second operation \textcircled{2}, the power sequence manager 121 may execute the power-on sequence PON_SEQ based on the loaded sequence instruction. The executing of the power-on sequence PON_SEQ may include sequentially outputting the plurality of enable signals, such as the first to fourth enable signals EN1 to EN4, to the power supply circuit 130. Blocks may be sequentially activated in response to enable signals. For example, because the first to fourth enable signals EN1 to EN4 are sequentially provided, the fourth power block PBK4, the third power block PBK3, the first power block PBK1, and the second power block PBK2 may be sequentially activated.

In a third operation \textcircled{3}, the power sequence manager 121 may update the sequence history information SH of the log register 123, based on executing the power-on sequence PON_SEQ. The updated sequence history information SH may include information about the history that the power-on sequence PON_SEQ is executed depending on the second operation \textcircled{2}.

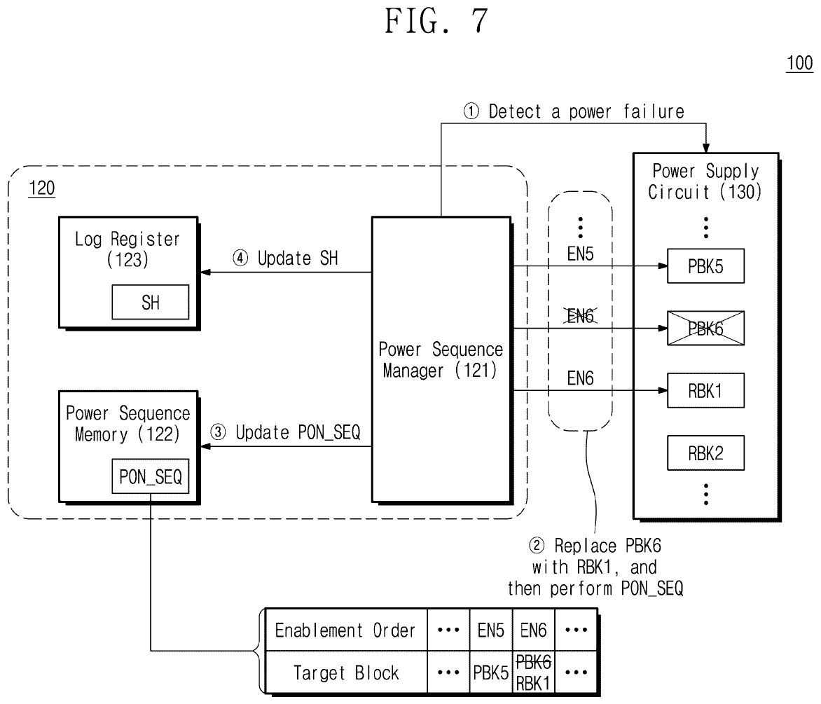

FIG. 7 is a diagram describing a method of operating a storage device according to some example embodiments of the present disclosure. Referring to FIG. 7, the storage device 100 may include the MCU 120 and the power supply circuit 130. The MCU 120 may include the power sequence manager 121, the power sequence memory 122, and the log register 123. The power supply circuit 130 may include a plurality of blocks such as the fifth power block PBK5, the sixth power block PBK6, the first recovery block RBK1, and the second recovery block RBK2.

Below, a method of operating the storage device 100 according to some example embodiments of the present disclosure will be described in detail.

In a first operation \textcircled{1}, the power sequence manager 121 may detect a power failure. For example, when the power-on sequence PON_SEQ fails or the voltage abnormality is caused in internal voltages, the power sequence manager 121 may again perform the power-on sequence PON_SEQ. When the power failure is caused by a permanently failed power block, the power-on sequence PON_SEQ again executed may again fail. The power sequence manager 121 may determine a failed power block causing the power failure in the power-on sequence PON_SEQ again executed. For example, the power-on sequence PON_SEQ again executed may fail due to a permanent damage of the sixth power block PBK6 corresponding to the sixth enable signal EN6.

In a second operation \textcircled{2}, the power sequence manager 121 may select the first recovery block RBK1 among a plurality of recovery blocks including the first and second recovery blocks RBK1 and RBK2. The power sequence manager 121 may replace the failed sixth power block PBK6 with the first recovery block RBK1. The power sequence manager 121 may execute the power-on sequence PON_SEQ by using the first recovery block RBK1. In this case, the sixth enable signal EN6 may be provided to the first recovery block RBK1 instead of the failed sixth power block PBK6.

In a third operation \textcircled{3}, the power sequence manager 121 may update a sequence instruction corresponding to the power-on sequence PON_SEQ present in the power sequence memory 122. For example, the enablement order item in the sequence instruction may include the sixth enable signal EN6. The target block item in the sequence instruction may include a block mapped to the sixth enable signal EN6. The power sequence manager 121 may change the block mapped to the sixth enable signal EN6 from the sixth power block PBK6 to the first recovery block RBK1 in the target block item of the sequence instruction.

In a fourth operation \textcircled{4}, the power sequence manager 121 may update the sequence history information SH of the log register 123, based on executing the power-on sequence PON_SEQ by using the first recovery block RBK1. The updated sequence history information SH may include information about the history that the failed sixth power block PBK6 is changed to the first recovery block RBK1 and the history that the power-on sequence PON_SEQ is executed by using the first recovery block RBK1.

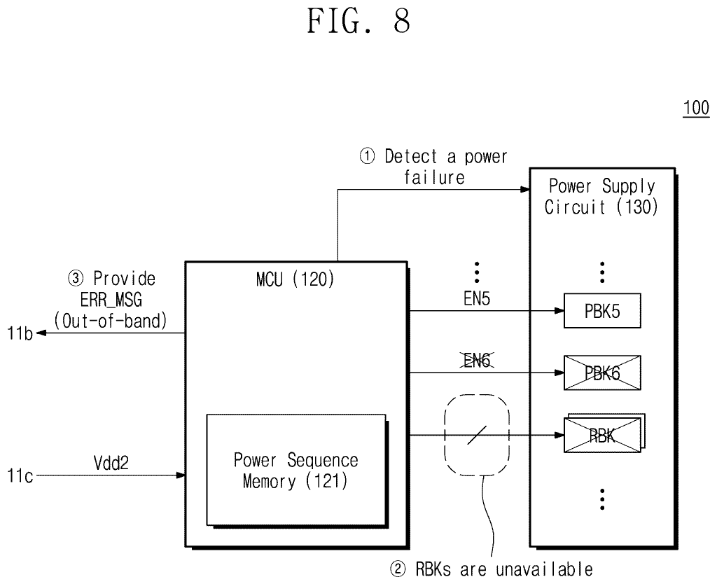

FIG. 8 is a diagram describing a method of operating a storage device according to some example embodiments of the present disclosure. Referring to FIG. 8, the storage device 100 may include the MCU 120 and the power supply circuit 130. The MCU 120 may include the power sequence manager 121. The power supply circuit 130 may include a plurality of blocks such as the fifth power block PBK5, the sixth power block PBK6, and the plurality of recovery blocks RBK.

Below, a method of operating the storage device 100 according to some example embodiments of the present disclosure will be described in detail.

In a first operation \textcircled{1}, the power sequence manager 121 may detect a power failure. For example, the power sequence manager 121 may detect the power failure through the monitoring operation, may again execute the power-on sequence PON_SEQ, and may detect that the power-on sequence PON_SEQ again executed fails due to a permanent damage of the sixth power block PBK6.

In a second operation \textcircled{2}, the power sequence manager 121 may determine whether an available recovery block is present in the plurality of recovery blocks RBK. In some examples, all the recovery blocks RBK may be unavailable. Because the sixth power block PBK6 is damaged by the permanent cause and a recovery block capable of replacing the sixth power block PBK6 does not exist, it may be difficult to solve the power failure.

In a third operation \textcircled{3}, the power sequence manager 121 may provide the BMC 11b with an error message ERR_MSG describing that the power failure is permanent and is incapable of being solved. The error message ERR_MSG may be transmitted by using the out-of-band communication between the BMC 11b and the MCU 120. Also, because the MCU 120 including the power sequence manager 121 is driven based on the second power supply voltage Vdd2 received from the host power supply circuit 11c, the MCU 120 may stably operate even though a power block providing an internal voltage has a permanent damage.

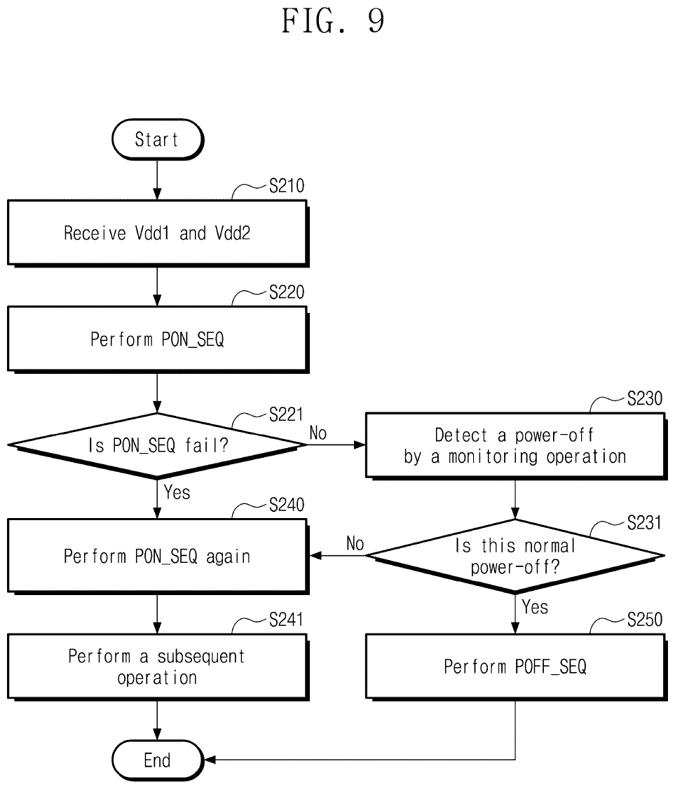

FIG. 9 is a flowchart describing a method of operating a storage device according to some example embodiments of the present disclosure. Referring to FIG. 9, a storage device may communicate with a host device. The storage device may correspond to the storage device 100 of FIGS. 1, 3, 4, 5, 6, 7, and 8.

In operation S210, the storage device may receive the first power supply voltage Vdd1 and the second power supply voltage Vdd2 from the host device. A voltage level of the first power supply voltage Vdd1 may be higher than a voltage level of the second power supply voltage Vdd2. The storage device may include an MCU and a power supply circuit. The first power supply voltage Vdd1 may be provided to the power supply circuit for generating internal voltages. The second power supply voltage Vdd2 may be provided to the MCU.

In operation S220, the MCU of the storage device may execute the power-on sequence PON_SEQ. The power-on sequence PON_SEQ may indicate sequentially activating power blocks of the power supply circuit depending on an enablement order and generating internal voltages based on the first power supply voltage Vdd1 through the activated power blocks.

In operation S221, the MCU of the storage device may perform the monitoring operation for detecting whether the power-on sequence PON_SEQ fails. The MCU may determine whether the power-on sequence PON_SEQ fails, through the monitoring operation. When the power-on sequence PON_SEQ is successfully executed, the storage device may perform operation S230. When the power-on sequence PON_SEQ fails, the storage device may perform operation S240.

In operation S230, the MCU of the storage device may perform the monitoring operation for detecting the voltage abnormality of internal voltages generated based on the power-on sequence PON_SEQ successfully executed. The MCU may detect a power-off event through the monitoring operation.

In operation S231, the MCU of the storage device may determine whether the detected power-off event is a normal power-off event. When the power-off event corresponds to an abnormal power-off event, the storage device may perform operation S240. When the power-off event corresponds to a normal power-off event, the storage device may perform operation S250.

In operation S240, the MCU of the storage device may again execute the power-on sequence PON_SEQ. When the failure of the power-on sequence PON_SEQ detected in operation S221 or the non-abnormal power-off event detected in operation S231 is due to a transient cause, the power-on sequence PON_SEQ again executed may succeed. When the failure of the power-on sequence PON_SEQ detected in operation S221 or the non-abnormal power-off event detected in operation S231 is due to a permanent cause, the power-on sequence PON_SEQ again executed may fail.

In operation S241, the MCU 120 may perform a subsequent operation depending on a result of the power-on sequence PON_SEQ again executed. For example, the MCU may monitor internal voltages generated by the power-on sequence PON_SEQ successfully executed. As another example, the MCU may replace a power block causing the failure of the power-on sequence PON_SEQ with a recovery block or may provide an error message to the host device.

Returning to operation S231, when the power-off event corresponds to a normal power-off event, the storage device may perform operation S250. The normal power-off event may mean a normal end operation according to a request of the host device. In operation S250, the storage device may perform the power-off sequence POFF_SEQ. As the power-off sequence POFF_SEQ is performed, data which are under processing or are buffered may be stored in a non-volatile memory device, and power blocks which provide the internal voltages may be sequentially deactivated.

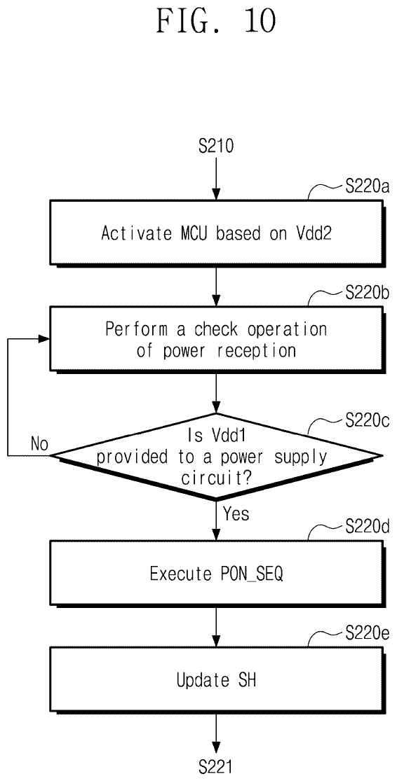

FIG. 10 is a flowchart describing an example of some operations of FIG. 9, according to some example embodiments of the present disclosure. Referring to FIGS. 9 and 10, the storage device 100 may perform operation S210 and may then perform operation S220a.

In operation S220a, the MCU of the storage device may be activated based on the second power supply voltage Vdd2. Because the second power supply voltage Vdd2 is a constant power supply voltage, the MCU may stably operate based on the second power supply voltage Vdd2.

In operation S220b, the MCU of the storage device may perform a check operation of power reception. For example, the MCU may monitor whether the power supply circuit of the storage device normally receives the first power supply voltage Vdd1 from the host device.

In operation S220c, the MCU of the storage device may determine whether the first power supply voltage Vdd1 is provided to the power supply circuit, based on the monitoring operation. When it is determined that the power supply circuit fails to receive the first power supply voltage Vdd1, the storage device may again perform operation S220b. When it is determined that the power supply circuit receives the first power supply voltage Vdd1, the storage device may perform operation S220d.

In operation S220d, the MCU of the storage device may execute the power-on sequence PON_SEQ. For example, depending on an enablement order defined in the power-on sequence PON_SEQ, the MCU may sequentially activate power blocks of the power supply circuit. The activated power block may generate an internal voltage based on the first power supply voltage Vdd1.

In operation S220e, the MCU of the storage device may update the sequence history information SH based on executing the power-on sequence PON_SEQ. The sequence history information SH may include information about the history that the power-on sequence PON_SEQ in operation S220d is executed. Afterwards, the storage device may perform operation S221.

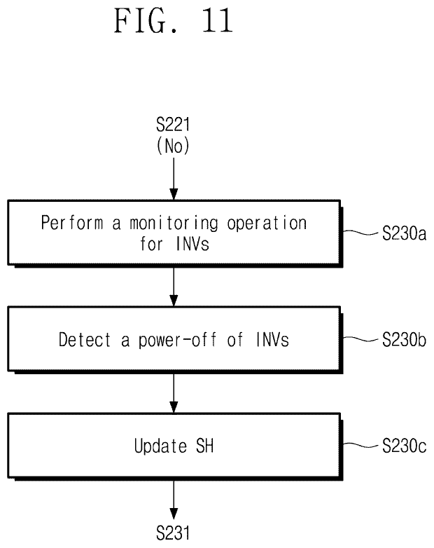

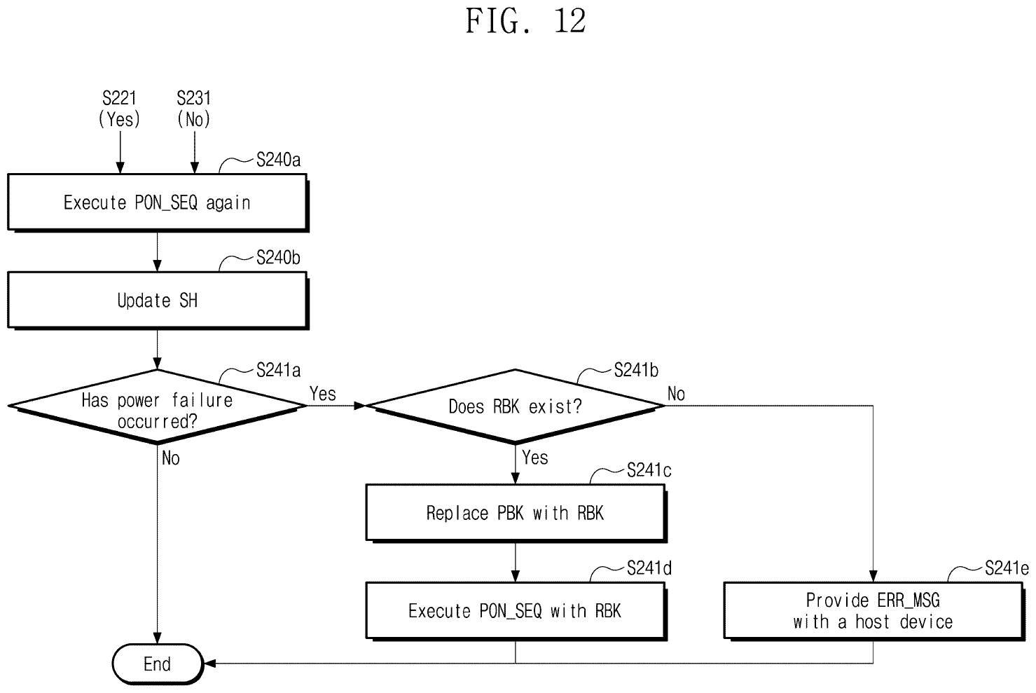

FIG. 11 is a flowchart describing an example of some operations of FIG. 9, according to some example embodiments of the present disclosure. Referring to FIGS. 9 and 11, the storage device may perform operation S230a in response to that it is determined in operation S221 that the power-on sequence PON_SEQ does not fail (for example, that the power-on sequence PON_SEQ is successfully executed).

In operation S230a, the MCU of the storage device may perform the monitoring operation for detecting whether the voltage abnormality is caused in the internal voltages INV generated by on the power-on sequence PON_SEQ. The voltage abnormality may mean that each of the internal voltages INV has a voltage level out of a designed voltage level range (e.g., that each of the internal voltages INV has a voltage level which is not a transient noise level but a voltage level within a range that a normal operation is impossible).

In operation S230b, the MCU of the storage device may detect whether a power-off event occurs in the internal voltages INV, based on the monitoring operation. For example, the MCU may detect that at least one of the internal voltages INV has a low voltage level out of the designed voltage level range.

In operation S230c, the MCU of the storage device may update the sequence history information SH based on detecting the power-off event from the internal voltages INV. The updated sequence history information SH may include information about the history that the power-off event is detected from the internal voltages INV. Afterwards, the storage device may perform operation S231.

FIG. 12 is a flowchart describing an example of some operations of FIG. 9, according to some example embodiments of the present disclosure. Referring to FIGS. 9 and 12, the storage device may perform operation S240a in response to that it is determined in operation S221 that the power-on sequence PON_SEQ fails. Alternatively, the storage device may perform operation S240a in response to that it is determined in operation S231 that the detected power-off event is not a normal power-off event (for example, regardless of the normal end procedure by the host device).

In operation S240a, the MCU of the storage device may again execute the power-on sequence PON_SEQ. For example, because the failure of the power-on sequence PON_SEQ or the abnormal power-off event is due to a transient cause, the MCU may again perform the power-on sequence PON_SEQ of the same content before determining a permanent damage of the power block PBK.

In operation S240b, the MCU of the storage device may update the sequence history information SH based on again executing the power-on sequence PON_SEQ. The updated sequence history information SH may include information about the history that the power-on sequence PON_SEQ is again executed in operation S240a.

In operation S241a, the MCU of the storage device may perform the monitoring operation for detecting whether the power-on sequence PON_SEQ again executed is successfully executed. The MCU may determine whether the power failure occurs in the power-on sequence PON_SEQ, based on the monitoring operation. When the power failure does not occur, the MCU may monitor the voltage abnormality of internal voltages without performing a separate operation for solving the power failure. When the power failure occurs, the storage device may perform operation S241b.

In operation S241b, the MCU of the storage device may determine whether the recovery block RBK is capable of replacing the power block PBK causing the power failure of the power-on sequence PON_SEQ is present in the storage device. When the recovery block RBK exists, the storage device may perform operation S241c. When the recovery block RBK does not exist, the storage device may perform operation S241e.

In operation S241c, the MCU of the storage device may replace the failed power block PBK causing the power failure of the power-on sequence PON_SEQ with the recovery block RBK. For example, the MCU of the storage device may connect function blocks associated with the failed power block PBK to the recovery block RBK instead of the failed power block PBK.

In operation S241d, the MCU of the storage device may execute the power-on sequence PON_SEQ by using the replaced recovery block RBK. In this case, in the power-on sequence PON_SEQ, the recovery block RBK may receive an enable signal instead of the failed power block PBK and may generate an internal voltage based on the first power supply voltage Vdd1 in response to the enable signal.

Returning to operation S241b, when the recovery block RBK capable of replacing the failed power block PBK does not exist, the storage device may perform operation S241. In operation S241, the MCU of the storage device may provide the error message ERR_MSG to the storage device. In some example embodiments, the MCU may be driven based on the second power supply voltage Vdd2 and may provide the error message ERR_MSG to the host device by using the out-of-band communication.

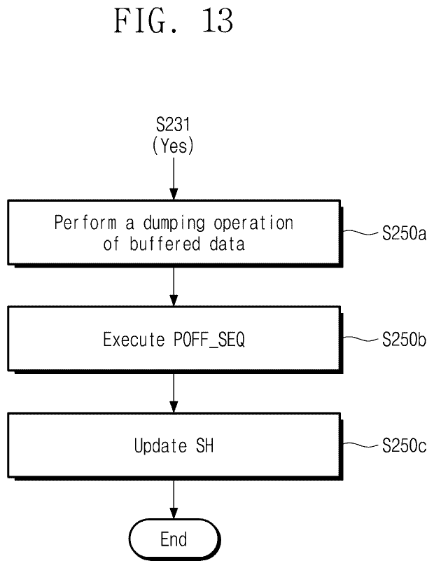

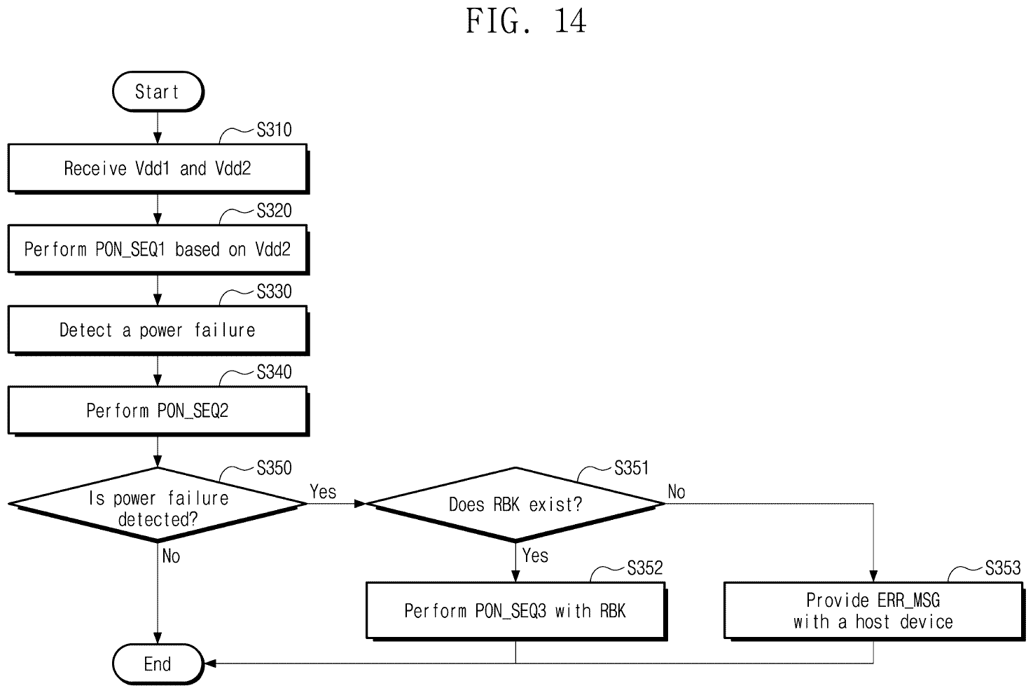

FIG. 13 is a flowchart describing an example of some operations of FIG. 9, according to some example embodiments of the present disclosure. Referring to FIGS. 9 and 13, the storage device may perform operation S250a in response to that it is determined in operation S231 that the detected power-off event is a normal power-off event (for example, that the power supply according to the normal end procedure by the host device starts to be blocked).

In operation S250a, the MCU of the storage device may notify the storage controller of the storage device that the power-off is normally performed. The storage controller may perform a dumping operation of data temporarily buffered in a buffer memory. For example, before the power supply is blocked, the storage controller may back up the data buffered in a volatile memory device of the storage controller to a non-volatile memory device. As the buffered data are backed up to the non-volatile memory device, the data may be maintained even after the power supply is blocked.

In operation S250b, the MCU of the storage device may execute the power-off sequence POFF_SEQ. The power-off sequence POFF_SEQ may indicate an operation of normally deactivating power blocks, which generates internal voltage depending on the power-on sequence PON_SEQ, depending on a disablement order defined in the power-off sequence POFF_SEQ.

In operation S250c, the MCU of the storage device may update the sequence history information SH based on executing the power-off sequence POFF_SEQ. The updated sequence history information SH may include information about the history that the power-off sequence POFF_SEQ is executed. Operation S250c may be performed before power blocks are blocked depending on operation S250b, may be performed before operation S250b, or may be performed in parallel with operation S250.

FIG. 14 is a flowchart describing a method of operating a storage device according to some example embodiments of the present disclosure. Referring to FIG. 14, a storage device may communicate with a host device. The storage device may include an MCU and a power supply circuit.

In operation S310, the storage device may receive the first power supply voltage Vdd1 and the second power supply voltage Vdd2 from the host device. The first power supply voltage Vdd1 may be provided to the power supply circuit. The second power supply voltage Vdd2 may be provided to the MCU. A voltage level of the first power supply voltage Vdd1 may be higher than a voltage level of the second power supply voltage Vdd2. The first power supply voltage Vdd1 may be referred to as a “main voltage”, and the second power supply voltage Vdd2 may be referred to as an “auxiliary voltage”.

In operation S320, the MCU of the storage device may execute a first power-on sequence PON_SEQ1 based on the second power supply voltage Vdd2. As power blocks are activated by the first power-on sequence PON_SEQ1, internal voltages may be sequentially generated. For example, depending on an enablement order defined in the first power-on sequence PON_SEQ1, the MCU may sequentially activate power blocks of the power supply circuit. The activated power block may generate an internal voltage based on the first power supply voltage Vdd1. The internal voltage may be provided to function blocks of the storage device or the MCU.

In operation S330, the MCU of the storage device may detect a power failure corresponding to the first power-on sequence PON_SEQ1. For example, when the first power-on sequence PON_SEQ1 fails, the MCU may determine that the power failure occurs. As another example, the MCU may monitor internal voltages generated by the first power-on sequence PON_SEQ1; when the voltage abnormality of the internal voltages is detected by the monitoring operation, the MCU may determine that the power failure occurs.

In operation S340, the MCU of the storage device may execute a second power-on sequence PON_SEQ2. An enablement order of the second power-on sequence PON_SEQ2 and blocks corresponding to the enablement order may be the same as an enablement order of the first power-on sequence PON_SEQ1 and blocks corresponding to the enablement order. That is, the MCU may again perform a power-on sequence of the same content before determining a permanent failure of a power block.

In operation S350, the MCU of the storage device may determine whether a power failure of the second power-on sequence PON_SEQ2 occurs. For example, when the second power-on sequence PON_SEQ2 fails, the MCU may determine that the power failure occurs and may perform operation S351. When the second power-on sequence PON_SEQ2 succeeds, the MCU may monitor the voltage abnormality of generated internal voltages without performing a separate operation for solving the permanent damage. When the voltage abnormality of internal voltages is detected, an operation of the storage device may be similar to that in operation S330.

In operation S352, the MCU of the storage device may determine whether the recovery block RBK capable of replacing the power block PBK causing the power failure is present in the power supply circuit. When the recovery block RBK exists, the storage device may perform operation S352. When the recovery block RBK does not exist, the storage device may perform operation S353.

In operation S351, the MCU of the storage device may replace a power block causing the power failure detected in operation S350 with the recovery block RBK. The MCU may execute a third power-on sequence PON_SEQ3 by using the replaced recovery block RBK. The recovery block RBK may be activated in the third power-on sequence PON_SEQ3 instead of the failed power block. The activated recovery block RBK may generate an internal voltage instead of the failed power block.

Also, the MCU of the storage device may include a power sequence memory and a log register. After the execution of the third power-on sequence PON_SEQ3, the MCU may update a sequence instruction corresponding to the first and second power-on sequences PON_SEQ1 and PON_SEQ2 stored in the power sequence memory, such that the sequence instruction includes information indicating that the recovery block RBK is used to replace the failed power block. The updated sequence instruction may indicate the recovery block RBK instead of the failed power block. After the execution of the third power-on sequence PON_SEQ3, the MCU may update sequence history information stored in the log register to include information about the history that the third power-on sequence PON_SEQ3 is executed. Afterwards, an operation of the storage device may be similar to that in operations S350.

Returning to operation S351, when the recovery block RBK capable of replacing the power block causing the power failure does not exist, the storage device may perform operation S353. In this case, when the recovery block RBK capable of replacing a permanently damaged power block does not exist, the storage device may be difficult to normally operate. The storage device may provide the BMC of the host device with the error message ERR_MSG describing that the power failure is permanent and is incapable of being solved.

In some example embodiments, because the MCU of the storage device is driven based on the second power supply voltage Vdd2, in spite of the voltage abnormality of an internal voltage, the MCU may stably provide the error message ERR_MSG to the host device. Also, because the MCU is capable of transmitting the error message ERR_MSG directly to the BMC by using the out-of-band communication instead of transmitting the error message ERR_MSG through the storage controller by using the in-band communication, even though the storage controller abnormally operates due to the voltage abnormality, the MCU may stably provide the error message ERR_MSG to the host device.

According to some example embodiments of the present disclosure, a storage device performing a power-on sequence, an electronic device including the same, and a method of operating the same are provided.

Also, a storage device which guarantees or improves the stable power supply by replacing a power block causing a permanent power failure with a recovery block and improves the stability of power management by managing the power management through a micro controller unit (MCU) by utilizing an auxiliary power being a constant power, an electronic device including the same, and a method of operating the same are provided.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

While the present disclosure has been described with reference to example embodiments thereof, it will be apparent to those of ordinary skill in the art that various changes and modifications may be made thereto without departing from the spirit and scope of the present disclosure as set forth in the following claims.

What is claimed is:

1. A method of operating a storage device which communicates with a host device, the method comprising:
receiving a first power supply voltage and a second power supply voltage from the host device;
executing, by a micro controller unit (MCU) of the storage device, a first power-on sequence for sequentially generating a plurality of internal voltages of the storage device based on the second power supply voltage;
detecting, by the MCU, a first power failure corresponding to the first power-on sequence; and
performing, by the MCU, a second power-on sequence for sequentially generating the plurality of internal voltages in response to detecting the first power failure.

2. The method of claim 1, wherein the storage device includes:
a storage controller configured to perform in-band communication with a processor of the host device,
wherein the MCU is configured to perform out-of-band communication with a baseboard management controller (BMC) of the host device.

3. The method of claim 1, wherein the executing of the first power-on sequence for sequentially generating the plurality of internal voltages of the storage device based on the second power supply voltage by the MCU of the storage device includes:
activating the MCU based on the second power supply voltage;
determining, by the activated MCU, whether the first power supply voltage is provided to a power supply circuit of the storage device;
loading, by the activated MCU, a sequence instruction defining an enablement order of a plurality of power blocks of the power supply circuit in response to determining that the first power supply voltage is provided to the power supply circuit;
executing, by the activated MCU, the first power-on sequence for sequentially generating the plurality of internal voltages depending on the enablement order, based on the loaded sequence instruction; and
updating, by the activated MCU, sequence history information based on executing the first power-on sequence.

4. The method of claim 3, wherein the performing of the second power-on sequence for sequentially generating the plurality of internal voltages in response to detecting the first power failure by the MCU includes:
loading, by the activated MCU, the sequence instruction in response to detecting the first power failure;
executing, by the activated MCU, the second power-on sequence for sequentially generating the plurality of internal voltages based on the loaded sequence instruction; and
further updating, by the activated MCU, the sequence history information based on executing the second power-on sequence.

5. The method of claim 3, wherein the MCU includes:
a power sequence manager configured to execute the first power-on sequence;
a power sequence memory configured to store the sequence instruction; and
a log register configured to store the sequence history information.

6. The method of claim 1, wherein the MCU is configured to detect the first power failure, based on failing in the execution of the first power-on sequence or based on detecting an abnormal power-off event through a monitoring operation of the plurality of internal voltages generated by the first power-on sequence.

7. The method of claim 1, further comprising:
determining, by the MCU, whether a second power failure of at least some of the plurality of internal voltages generated by the second power-on sequence occurs.

8. The method of claim 7, wherein
the storage device includes:
a plurality of power blocks configured to generate the plurality of internal voltages; and
a recovery block configured to replace a failed power block among the plurality of power blocks, and
the method further comprises:
determining, by the MCU, whether the recovery block configured to replace the failed power block causing the second power failure from among the plurality of power blocks exists, in response to determining that the second power failure occurs;
replacing, by the MCU, the failed power block with the recovery block in response to determining that the recovery block exists; and
performing, by the MCU, a third power-on sequence for sequentially generating the plurality of internal voltages by using the replaced recovery block.

9. The method of claim 8, further comprising:
updating, by the MCU, a sequence instruction corresponding to the second power-on sequence based on executing the third power-on sequence; and
updating, by the MCU, sequence history information based on executing the third power-on sequence.

10. The method of claim 9, wherein the updated sequence instruction indicates the recovery block instead of the failed power block.

11. The method of claim 7, wherein
the storage device includes:
a plurality of power blocks configured to generate the plurality of internal voltages; and
a recovery block configured to replace a failed power block among the plurality of power blocks, and
the method further comprises:
determining, by the MCU, whether the recovery block configured to replace the failed power block causing the second power failure from among the plurality of power blocks exists, in response to determining that the second power failure occurs; and
providing, by the MCU, an error message to the host device in response to determining that the recovery block does not exist.

12. The method of claim 11, wherein the MCU is configured to:
operate based on the second power supply voltage while providing the error message to the host device; and
provide the error message of a BMC of the host device by using out-of-band communication.

13. The method of claim 1, wherein the first power supply voltage is higher than the second power supply voltage.

14. The method of claim 1, wherein the MCU is configured to:
receive an internal voltage dedicated for the MCU from among the plurality of internal voltages generated by the first power-on sequence or the second power-on sequence; and
operate based on both the second power supply voltage and the internal voltage dedicated for the MCU.

15. The method of claim 1, wherein the MCU is configured to a power-off sequence for normally deactivating the plurality of internal voltages generated by the first power-on sequence or the second power-on sequence.

16. A storage device comprising:
a storage controller;
a non-volatile memory device;
a power supply circuit including a plurality of power blocks configured to generate a plurality of internal voltages to be provided to the storage controller and the non-volatile memory device based on a first power supply voltage received from a host device; and
a micro controller unit (MCU) configured to receive a second power supply voltage lower than the first power supply voltage from the host device and to execute a first power-on sequence based on the second power supply voltage,
the power supply circuit configured to sequentially active the plurality of power blocks depending on an enablement order defined in the first power-on sequence under control of the MCU.

17. The storage device of claim 16, wherein the MCU is configured to:
detect a first power failure, based on failing in the execution of the first power-on sequence or based on detecting an abnormal power-off event in the plurality of internal voltages generated by the plurality of power blocks activated by the first power-on sequence; and
execute a second power-on sequence defining the enablement order in response to detecting the first power failure.

18. The storage device of claim 17, wherein
the power supply circuit further includes:
a recovery block configured to replace a failed power block among the plurality of power blocks, and
the MCU is further configured to:
detect a second power failure corresponding to the second power-on sequence;
determine whether the recovery block configured to replace the failed power block causing the second power failure from among the plurality of power blocks exists, in response to detecting the second power failure;
replace the failed power block with the recovery block in response to determining that the recovery block exists; and
execute a third power-on sequence by using the replaced recovery block.

19. The storage device of claim 17, wherein
the power supply circuit further includes:
a recovery block configured to replace a failed power block among the plurality of power blocks, and
the MCU is further configured to:
detect a second power failure corresponding to the second power-on sequence;
determine whether the recovery block for replacing the failed power block causing the second power failure from among the plurality of power blocks exists, in response to detecting the second power failure; and
provide an error message to the host device by using out-of-band communication in response to determining that the recovery block does not exist.

20. An electronic device comprising:
a host device configured to generate a main voltage and an auxiliary voltage; and
a storage device including a power supply circuit configured to receive the main voltage and a micro controller unit (MCU) configured to receive the auxiliary voltage,
wherein the MCU is further configured to:
execute a power-on sequence based on the auxiliary voltage;
detect a power failure corresponding to the power-on sequence; and
again perform the power-on sequence in response to detecting the power failure, and
the storage device is configured to sequentially active a plurality of power blocks of the power supply circuit depending on an enablement order defined in the power-on sequence.
